(19) United States
(12) Patent Application Publication
(10) Pub. No.: US 2009/0136724 A1
(43) Pub. Date: May 28, 2009

(54) METHOD OF FABRICATING SEMICONDUCTOR DEVICE

(76) Inventor: Sang-Chul Kim, Eumseong-gun (KR)

Correspondence Address: SHERR & VAUGHN, PLLC, 620 HERNDON PARKWAY, SUITE 200, HERNDON, VA, 20170, US

(21) Appl. No.: 12/253,252

(22) Filed: Oct. 17, 2008

(30) Foreign Application Priority Data
Nov. 26, 2007 (KR) 10-2007-0120622

(51) Int. Cl. B32B 3/26; H01L 21/311; H01L 21/304

(52) U.S. Cl. 428/201; 438/700; 438/692; 257/E21.239; 257/E21.218

(57) ABSTRACT

Embodiments relate to a semiconductor device and to a method of fabricating a semiconductor device. According to embodiments, reliability may be enhanced by removing oxide from a barrier metal surface. According to embodiments, a method may include forming an insulating layer on and/or over a metal layer formed on and/or over a substrate, forming a via hole by etching the insulating layer to expose the metal layer, forming a trench by etching a portion of the insulating layer in an area having the via hole formed therein, forming a barrier metal layer on and/or over the insulating layer including the trench and the via hole, performing plasma processing on the barrier metal layer, and forming a seed Cu layer on the barrier metal layer.

The present application claims priority under 35 U.S.C. 119 to Korean Patent Application No. 10-2007-0120622 (filed on Nov. 26, 2007), which is hereby incorporated by reference in its entirety.

### BACKGROUND

To fabricate an ultra-highly integrated semiconductor device having an improved operational speed, it may be important to develop a multi-layered wire technology having lower parasitic RC. To form a line having a small parasitic RC, metal having low specific resistance may be used as a substance for a line, or an insulating layer may be formed of low-k substance. For example, Cu, Al, Ag, Au or the like, or an alloy thereof may be used as a line substance. Accordingly, it may be important to research and develop various lines using copper (Cu). Copper (Cu) may have a small specific resistance and may be an inexpensive metal. Additionally, a copper process may impose a lower burden. Unlike aluminum, copper may also have a strong tolerance against electromigration. Hence, Copper may be widely used as a substance for a via-contact or other lines, and may have certain advantageous characteristics. For example, copper may have high chemical affinity with various substances and may easily diffuse into a silicon substrate or a silicon oxide layer.

To prevent Cu diffusion and enhance adhesiveness, a barrier layer formed of Ti or Ta based alloy may be provided between a contact and a silicon oxide layer. Copper may oxidize easily. Thus if it is externally exposed, it may be easily oxidized. Once Cu is oxidized, resistance and stress of a line may be raised. This may degrade electrical characteristics of a chip. Hence, an oxidation preventing layer may be provided outside a Cu line layer. This may prevent oxidation of Cu. Since it may be difficult to form a Cu line pattern by etching, a single or dual damascene process may be used according to a line pattern structure.

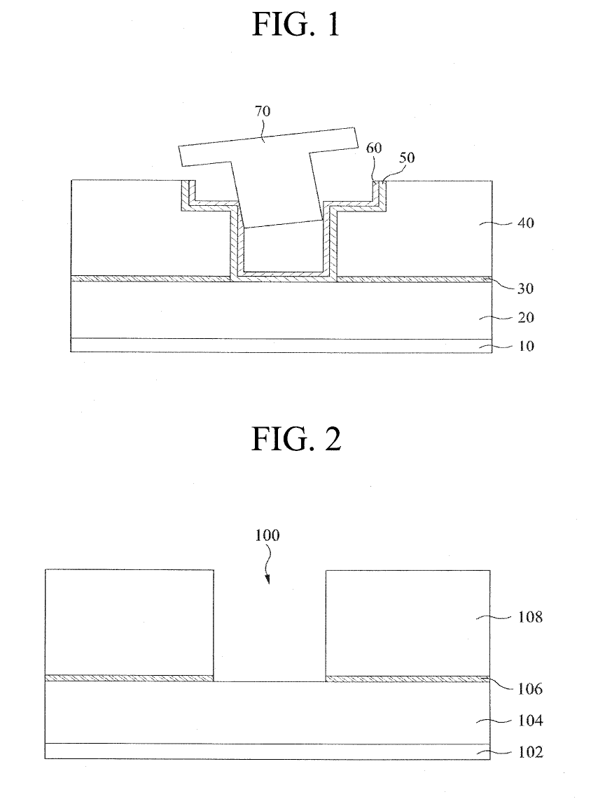

FIG. 1 illustrates a related art semiconductor device. Referring to FIG. 1, a semiconductor device may include substrate 10 and metal layer 20 on and/or over substrate 10. It may further include diffusion preventing layer 30 on and/or over metal layer 20 and insulating layer 40 on and/or over diffusion preventing layer 30. It may also include barrier metal layer 50 on and/or over insulating layer 40, including a trench and a via hole, and oxide layer 60 on and/or over barrier metal layer 50. Cu line 70 may be provided on and/or over insulating layer 40. In a method of manufacturing a semiconductor device and forming a line using Cu, barrier metal layer 50 may be formed of a Ti or Ta based metal alloy. This may prevent diffusion of Cu line 70 and may enhance adhesiveness. Because, however, oxide layer 60 may be formed on and/or over a surface of barrier metal layer 50, it may prevent diffusion and enhance adhesiveness by natural oxidation. A function of barrier metal layer 50 may therefore be degraded. A degraded adhesiveness between Cu line 70 and barrier metal layer 50 may cause a problem in that Cu line 70 may be stripped by thermal stress in annealing and mechanical force in CMP. Moreover, stripped Cu line 70, which may be attributed to oxide layer 60, may degrade a reliability of electromigration (EM) and stress migration (SM).

### SUMMARY

Embodiments relate to a semiconductor device. Embodiments relate to a method of fabricating a semiconductor device. Embodiments may enhance reliability by removing an oxide layer from a barrier metal surface.

According to embodiments, a method of fabricating a semiconductor device may enhance adhesiveness between a barrier metal layer and a seed Cu layer formed on and/or over the barrier metal layer by removing an oxide layer generated by natural oxidation on and/or over a surface of the barrier metal layer, which may maximize reliability of a semiconductor device.

According to embodiments, a method of fabricating a semiconductor device may include at least one of the following. Forming an insulating layer on and/or over a metal layer formed on and/or over a substrate. Forming a via hole by etching the insulating layer to expose the metal layer. Forming a trench by etching a portion of the insulating layer in an area having the via hole formed therein. Forming a barrier metal layer on and/or over the insulating layer including the trench and the via hole. Performing plasma processing on and/or over the barrier metal layer. Forming a seed Cu layer on and/or over the barrier metal layer.

According to embodiments, a method may also include forming a diffusion preventing layer on and/or under the metal layer and the seed Cu layer. According to embodiments, the plasma processing may be performed using a mixed gas containing H2. According to embodiments, the mixed gas containing H2 may include at least one of H2, SiH4, HF, NH3, and any combinations thereof.

According to embodiments, the plasma processing may be performed using one of Ar gas and N2 gas. According to embodiments, a process ambience of the plasma processing may include an RF power of approximately 100˜1,000 W and a DC bias of approximately 100˜1,000 W.

According to embodiments, forming the seed Cu layer may include forming a second metal layer on and/or over the barrier metal layer by electroplating and performing CMP on the second metal layer, which may expose the insulating layer. According to embodiments, the barrier metal layer may include at least one of Ta, TaN, TaSiN, TiSiN, Ru, and any alloys thereof.

According to embodiments, adhesiveness between a barrier metal layer and a seed Cu layer may be increased by performing H2 plasma processing on oxide naturally formed on the barrier metal layer. This may enhance a reliability of electromigration (EM) and stress migration (SM) of a semiconductor device. According to embodiments, productivity may thus be raised.

### DRAWINGS

Example FIG. 1 is a diagram of a semiconductor device.

Example FIGS. 2-6 are cross-sectional diagrams illustrating a semiconductor device and a method of fabricating a semiconductor device according to embodiments.

### DESCRIPTION

Example FIGS. 2-6 are cross-sectional diagrams illustrating a semiconductor device and a method of fabricating a semiconductor device according to embodiments. Referring to example FIGS. 2-6, a method of fabricating a semiconductor device according to embodiments may include forming insulating layer 108 on and/or over metal layer 104 formed on and/or over substrate 102. It may also include forming via hole 100 by etching insulating layer 108 to expose metal layer 104, and forming trench 110 by etching a portion of insulating layer 108 corresponding to an area having via hole 100 formed therein. A method may also include forming barrier metal layer 112 on and/or over insulating layer 108, including trench 110 and via hole 110. It may further include performing H2 plasma processing on barrier metal layer 112, and forming seed Cu layer 116a on and/or over barrier metal layer 112.

Referring to example FIG. 2, metal layer 104 may be formed on and/or over semiconductor substrate 102. According to embodiments, metal layer 104 may be formed on and/or over semiconductor substrate 102 by deposition, such as sputtering or other known processes. According to embodiments, metal layer 104 may be formed of one of Mo, Ti, Cu, AlNd, Al, Cr, Mo alloy, Cu alloy, and Al alloy, and other known materials, and may have a single-layer or multi-layer structure. According to embodiments, diffusion preventing layer 106, which may prevent a metal substance from diffusing into semiconductor substrate 102, may be provided. According to embodiments, diffusion preventing layer 106 may be provided between semiconductor substrate 102 and metal layer 104. According to embodiments, insulating layer 108 may be formed on and/or over metal layer 104. Insulating layer 108 may be formed by a deposition process, such as PECVD, for example, although other known processes could be used. Insulating layer 108 may use inorganic substance such as silicon oxide (SiOx), silicon nitride (SiNx), and/or other known materials. According to embodiments, insulating layer 108 may instead use an organic substance. According to embodiments, diffusion preventing layer 106 may be provided between metal layer 104 and insulating layer 108. Diffusion preventing layer 106 may prevent metal layer 104 from diffusing into an upper layer. According to embodiments, via hole 100 may be formed and may expose metal layer 104. Via hole 100 may be formed by photolithography using a mask in a manner of perforating both of insulating layer 108 and diffusion preventing layer 106, and may expose metal layer 104.

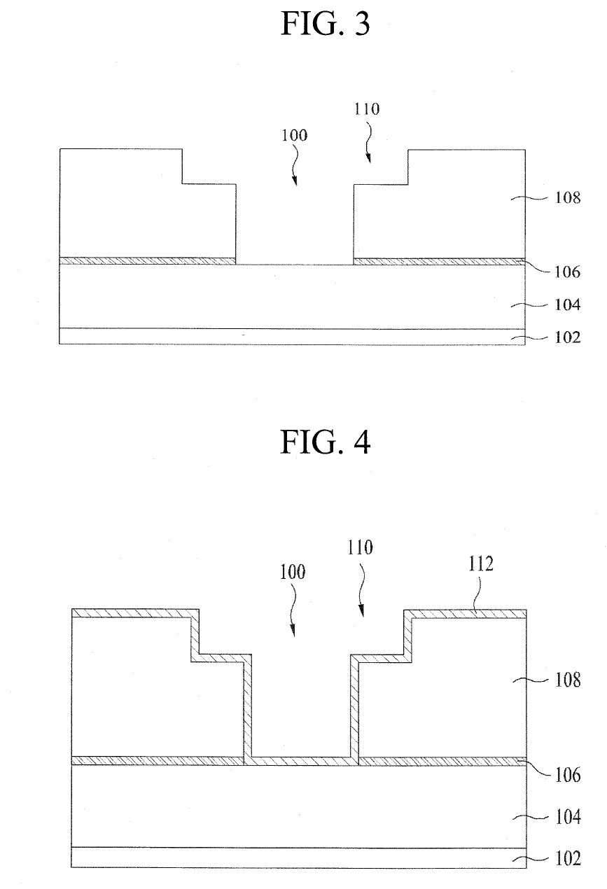

Referring to example FIG. 3, trench 110 may be formed in an area where via hole 100 may be formed. According to embodiments, trench 110 may be formed by photolithography using a mask, by etching right and left portions of insulating layer 108 in an area having via hole 100 formed therein.

Referring to example FIG. 4, barrier metal layer 112 may be formed on and/or over insulating layer 108, including via hole 100 and trench 110. According to embodiments, barrier metal layer 112 may be formed by a deposition process, such as CVD (Chemical Vapor Deposition), ALD (Atomic Layer Deposition), PVD (Physical Vapor Deposition), and/or other known processes. Barrier metal layer 112 may be formed of at least one of Ta, TaN, TaSiN, TiSiN, Ru, and other known materials.

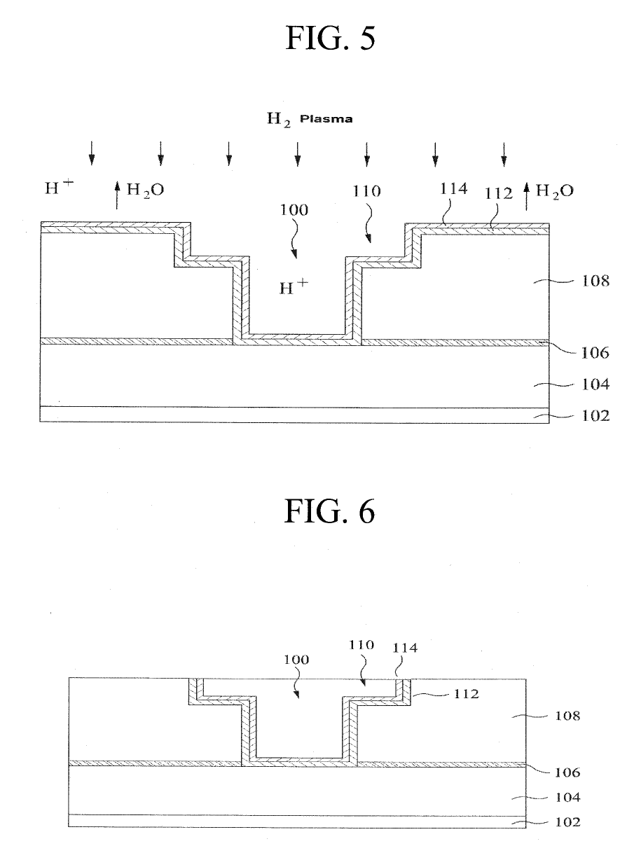

Referring to example FIG. 5, after barrier metal layer 112 has been formed, plasma processing may performed and may remove oxide generated by natural oxidation. According to embodiments, the oxide may include TaxOy or TixOy. The plasma processing may be performed using a mixed gas containing H2. According to embodiments, the mixed gas containing H2 may include at least one of H₂, SiH₄, HF, and NH₃, or any combination thereof. According to embodiments, the plasma processing may be performed using a gas of at least one of Ar and N₂. A process ambience for the plasma processing may include using a RF power of approximately 100 to 1,000 W and a DC bias of approximately 100 to 1,000 W. According to embodiments, oxygen of the oxide (TaxOy or TixOy) formed on and/or over barrier metal layer 112 may react with hydrogen of H₂, and may form H₂O. Second metal layer 114 may be formed on and/or over barrier metal layer 112 from which the oxide has been removed. According to embodiments, second metal layer 114 may be formed on and/or over barrier metal layer 112 and may fill up via hole 100 and trench 110 by ECP (Electro Chemical Plating).

Referring to example FIG. 6, a Cu layer may be deposited on and/or over insulating layer 108 and seed Cu layer 116 may be formed, for example by polishing barrier metal layer 112 and second metal layer 114 using chemical mechanical polishing (CMP). This may expose a surface of insulating layer 108. According to embodiments, adhesiveness may be increased between barrier metal layer 112 and seed Cu layer 116 by performing H2 plasma processing on oxide, which may form naturally on barrier metal layer 112. This may enhance a reliability of electromigration (EM) and stress migration (SM) of a semiconductor device. According to embodiments, productivity may be increased as well.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method, comprising:
forming an insulating layer over a metal layer formed over a substrate;
forming a via hole by etching the insulating layer to expose the metal layer;
forming a trench by etching a portion of the insulating layer in an area having the via hole formed therein;
forming a barrier metal layer over the insulating layer including the trench and the via hole;
performing plasma processing on the barrier metal layer; and
forming a seed Cu layer over the barrier metal layer.

2. The method of claim 1, comprising forming a diffusion preventing layer at least one of over and under the metal layer and the seed Cu layer.

3. The method of claim 3, wherein the plasma processing is performed using a mixed gas comprising H2.

4. The method of claim 3, wherein the mixed gas containing H2 comprises at least one of H₂, SiH₄, HF, and NH₃, and any combinations thereof.

5. The method of claim 1, wherein the plasma processing is performed using one of Ar gas and N₂ gas.

6. The method of claim 1, wherein the plasma processing is performed using a RF power of approximately 100˜1,000 W and a DC bias of approximately 100˜1,000 W.

7. The method of claim 1, wherein forming the seed Cu layer comprises:
forming a second metal layer over the barrier metal layer by electroplating; and
performing chemical mechanical polishing (CMP) on the second metal layer to expose the insulating layer.

8. The method of claim 7, comprising depositing a Cu layer over the insulating layer.

9. The method of claim 7, wherein the barrier metal layer comprises at least one of Ta, TaN, TaSiN, TiSiN, and Ru, and any alloys thereof.

10. The method of claim 1, wherein the metal layer comprises at least one of Mo, Ti, Cu, AlNd, Al, Cr, Mo alloy, Cu alloy, and Al alloy.

11. The method of claim 10, wherein the metal layer comprises one of a single-layer and a multi-layer structure.

12. The method of claim 1, wherein the insulating layer comprises silicon oxide and silicon nitride.

13. A device, comprising:
a metal layer over a substrate;
an insulating layer over the metal layer;
a via hole formed within the insulating layer exposing a portion of the metal layer;
a trench by formed within a portion of the insulating layer at an area having the via hole formed therein;
a barrier metal layer over the insulating layer, including the trench and the via hole; and
a seed Cu layer over the barrier metal layer, wherein a plasma process is performed on the barrier metal layer prior to forming the seed Cu layer.

14. The device of claim 13, comprising a diffusion preventing layer formed at least one of over and under the metal layer and the seed Cu layer.

15. The device of claim 13, wherein the plasma process is performed using one of Ar gas and N₂ gas.

16. The device of claim 13, wherein the plasma process is performed using a RF power of approximately 100 to 1,000 W and a DC bias of approximately 100 to 1,000 W.

17. The device of claim 13, wherein forming the seed Cu layer comprises:
forming a second metal layer over the barrier metal layer by electroplating; and
performing chemical mechanical polishing (CMP) on the second metal layer to expose the insulating layer.

18. The device of claim 13, wherein the barrier metal layer comprises at least one of Ta, TaN, TaSiN, TiSiN, and Ru, and any alloys thereof.

19. The device of claim 13, wherein the metal layer comprises at least one of Mo, Ti, Cu, AlNd, Al, Cr, Mo alloy, Cu alloy, and Al alloy, and wherein the metal layer comprises one of a single-layer and a multi-layer structure.

20. The device of claim 13, wherein the insulating layer comprises silicon oxide and silicon nitride.
